(19) United States
(12) Patent Application Publication
(10) Pub. No.: US 2026/0136923 A1
(43) Pub. Date: May 14, 2026

(54) HYBRID BONDING FOR THERMAL DISSIPATION

(71) Applicant: INTERNATIONAL BUSINESS MACHINES CORPORATION, Armonk, NY (US)

(72) Inventors: Sarabjot Singh, Albany, NY (US); Ruilong Xie, Niskayuna, NY (US); Dureseti Chidambarrao, Weston, CT (US); Daniel Charles Edelstein, White Plains, NY (US)

(21) Appl. No.: 18/947,723

(22) Filed: Nov. 14, 2024

(51) Int. Cl. H01L 23/367; H01L 21/683; H01L 23/00; H01L 23/373

(52) U.S. Cl. CPC H10W 40/22; H10P 72/70; H10W 40/258; H10W 72/242; H10W 72/322; H10W 90/734

(57) ABSTRACT

Semiconductor devices and methods of forming the same include a device layer, a back-end-of-line (BEOL) layer on the device layer, a combined bonding layer, and a handler wafer. A heat-conducting channel is partially embedded in the combined bonding layer and partially embedded in the handler wafer.

### BACKGROUND

The present invention generally relates to semiconductor device fabrication and, more particularly, to thermal dissipation for bonded layers.

Heat management in semiconductor devices poses a challenge, as heat is generated in the operation of transistors and even in the transmission of signals through passive structures such as interconnects. While there are a number of ways that heat from a device can be dissipated, that heat first needs to travel from the structure that created it to whatever heat removal mechanism is used. In devices with backside power distribution networks, a handler wafer may be used to manipulate the device during processing. This handler wafer can impede heat dissipation.

### SUMMARY

A semiconductor device includes a device layer, a back-end-of-line (BEOL) layer on the device layer, a combined bonding layer, and a handler wafer. A heat-conducting channel is partially embedded in the combined bonding layer and partially embedded in the handler wafer.

A semiconductor device includes a device layer, a BEOL layer on the device layer, and a backside power distribution network on a side of the device layer that is opposite to the BEOL layer. There is a combined bonding layer and a handler wafer, with heat-conducting channels that are partially embedded in the combined bonding layer and partially embedded in the handler wafer.

A method of forming a semiconductor device includes forming first trenches in a first bonding layer that is on a device layer. First heat conducting structures are formed in the first trenches. Second trenches are formed in a second bonding layer that is on a handler wafer. A liner is formed in the second trenches. Second heat conducting structures are formed in the second trenches. The first bonding layer is bonded to the second bonding layer, with the first heat conducting structures bonding to the second heat conducting structures.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional diagram of a step in the fabrication of a semiconductor device with heat conducting channels, showing the formation of a device layer and back-end-of-line (BEOL) layers on a semiconductor substrate, in accordance with an embodiment of the present invention;

FIG. 2 is a cross-sectional diagram of a step in the fabrication of a semiconductor device with heat conducting channels, showing the formation of a first bonding layer on the BEOL layers, in accordance with an embodiment of the present invention;

FIG. 3 is a cross-sectional diagram of a step in the fabrication of a semiconductor device with heat conducting channels, showing the formation of trenches in the first bonding layer, in accordance with an embodiment of the present invention;

FIG. 4 is a cross-sectional diagram of a step in the fabrication of a semiconductor device with heat conducting channels, showing the formation of first heat conducting structures in the first bonding layer, in accordance with an embodiment of the present invention;

FIG. 5 is a cross-sectional diagram of a step in the fabrication of a semiconductor device with heat conducting channels, showing the formation of a second bonding layer on a handler wafer, in accordance with an embodiment of the present invention;

FIG. 6 is a cross-sectional diagram of a step in the fabrication of a semiconductor device with heat conducting channels, showing the formation of trenches in the second bonding layer and in the handler wafer, in accordance with an embodiment of the present invention;

FIG. 7 is a cross-sectional diagram of a step in the fabrication of a semiconductor device with heat conducting channels, showing the deposition of liner material on the second bonding layer and the handler wafer, in accordance with an embodiment of the present invention;

FIG. 8 is a cross-sectional diagram of a step in the fabrication of a semiconductor device with heat conducting channels, showing the chamfering of the liner material to form chamfered liners in the trenches, in accordance with an embodiment of the present invention;

FIG. 9 is a cross-sectional diagram of a step in the fabrication of a semiconductor device with heat conducting channels, showing the formation of heat conducting material in the trenches to form second heat conducting structures, in accordance with an embodiment of the present invention;

FIG. 10 is a cross-sectional diagram of a step in the fabrication of a semiconductor device with heat conducting channels, showing hybrid bonding between the first bonding layer and the second bonding layer and between the first heat conducting structures and the second heat conducting structures, in accordance with an embodiment of the present invention;

FIG. 11 is a cross-sectional diagram of a step in the fabrication of a semiconductor device with heat conducting channels, showing the formation of backside power distribution network, in accordance with an embodiment of the present invention; and

FIG. 12 is a block/flow diagram of a method for fabricating a semiconductor device with heat conducting channels, in accordance with an embodiment of the present invention.

### DETAILED DESCRIPTION

When fabricating a semiconductor device with a backside power distribution network (BSPDN) or backside power rails (BPRs), heat-conducting structures may be formed within the handler wafer and the bonding layer(s) that hold the handler wafer to the device. These heat conducting structures help to carry heat away from the heat-generating elements of the semiconductor device, where it can be dissipated by active or passive means.

To accomplish this, first trenches may be formed within a first bonding layer on the device wafer, which may be filled with a heat-conducting material. Second trenches may similarly be formed within a second bonding layer on the handler wafer, with those trenches extending into the bulk of the handler wafer itself, and the second trenches may also be filled with heat-conducting material. When the handler wafer is subsequently bonded to the device wafer, the trenches are aligned so that the conductive material aligns and forms heat channels that extend from the device layer to the handler wafer.

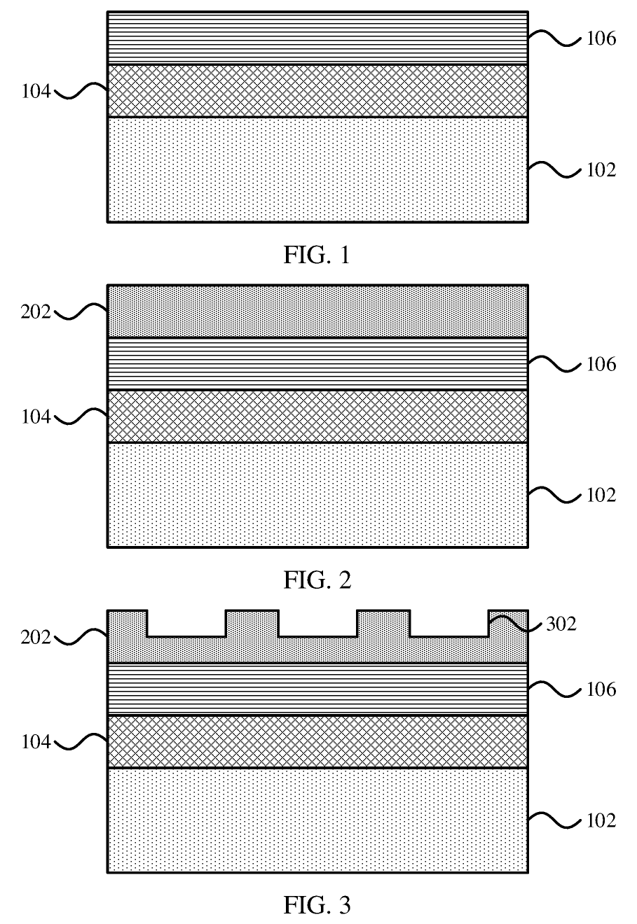

Referring now to FIG. 1, a cross-sectional view of a step in the fabrication of a semiconductor device is shown. A semiconductor substrate 102 is shown with a device layer 104 on top of it. The device layer 104 may include any appropriate semiconductor components, including active components such as transistors and passive components such as resistors, capacitors, inductors, and transmission lines. Back-end-of-line (BEOL) layers 106 are formed on top of the device layer 104 and provide power and signal communication to the components of the device layer 104.

The semiconductor substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

The components of the device layer 104 may include any of a variety of semiconductor components. Exemplary types of semiconductor components include planar field effect transistors (FETs), fin FETs, vertical transfer FETs, complementary FETs, stacked FETs, junction FETs, bipolar junction transistors, and diodes. Passive components may include resistors, interconnects, vias, transmission lines, antennas, capacitors, and inductors. These components may be connected to one another within the device layer 104 and/or may be connected by signal interconnects in the BEOL layers 106. The device layer 104 may be formed by a series of processing steps that deposit material, photolithographically pattern that material, and remove parts of the material using appropriate etching processes. The space around the components of the device layer 104 may be filled with an interlayer dielectric material, such as silicon dioxide or a low-k dielectric.

During operation of the device, the components in the device layer 104 generate heat. This heat may result from active operation, such as during the operation of a transistor, or due to resistive losses as current passes through the components. The heat that is generated will spread through the surrounding materials according to the thermal conductivity of those materials. For example, the interlayer dielectric may be formed from silicon dioxide, which has a thermal conductivity between about 1.3W/mK and about 1.5W/mK.

The BEOL layers 106 may be formed as a series of dielectric layers, with trenches being formed in the dielectric layers and being filled with conductive material. The BEOL layers 106 may therefore include vias that connect an underlying layer to an overlying layer and interconnects that travel horizontally within a given dielectric layer to provide connection between two components. The BEOL layers 106 may furthermore include power lines that provide power to the device layer 104.

Referring now to FIG. 2, a cross-sectional view of a step in the fabrication of a semiconductor device is shown. A first bonding layer 202 is formed on the BEOL layers 106. The first bonding layer 202 may be formed from, e.g., silicon dioxide and may be deposited by any appropriate process, such as chemical vapor deposition (CVD). The top surface of the first bonding layer 202 may be polished smooth using a chemical mechanical planarization (CMP) process. CMP is performed using, e.g., a chemical or granular slurry and mechanical force to gradually remove upper layers of the device.

Referring now to FIG. 3, a cross-sectional view of a step in the fabrication of a semiconductor device is shown. Trenches 302 are formed in the first bonding layer 202. The trenches 302 may be formed by creating a photolithographic mask over the first bonding layer 202 and then performing a timed anisotropic etch. The mask may be produced by depositing a layer of mask material, such as silicon nitride and then applying a photoresist to the surface to be etched. The photoresist is exposed to a pattern of radiation and then the pattern is developed into the photoresist utilizing a resist developer. An anisotropic etch is used to remove mask material that is outside the pattern, thereby exposing parts of the top surface of the first bonding layer 202. A further etch may be performed to remove exposed material from the first bonding layer 202 to create the trenches 302. The remaining mask material may then be etched away by any appropriately selective isotropic or anisotropic etch, leaving the first bonding layer 202 exposed.

Reactive Ion Etching (RIE) is a form of plasma etching that can be used for the anisotropic etch, in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. As used herein, the term “selective” in reference to a material removal process denotes that the rate of material removal for a first material is greater than the rate of removal for at least another material of the structure to which the material removal process is being applied.

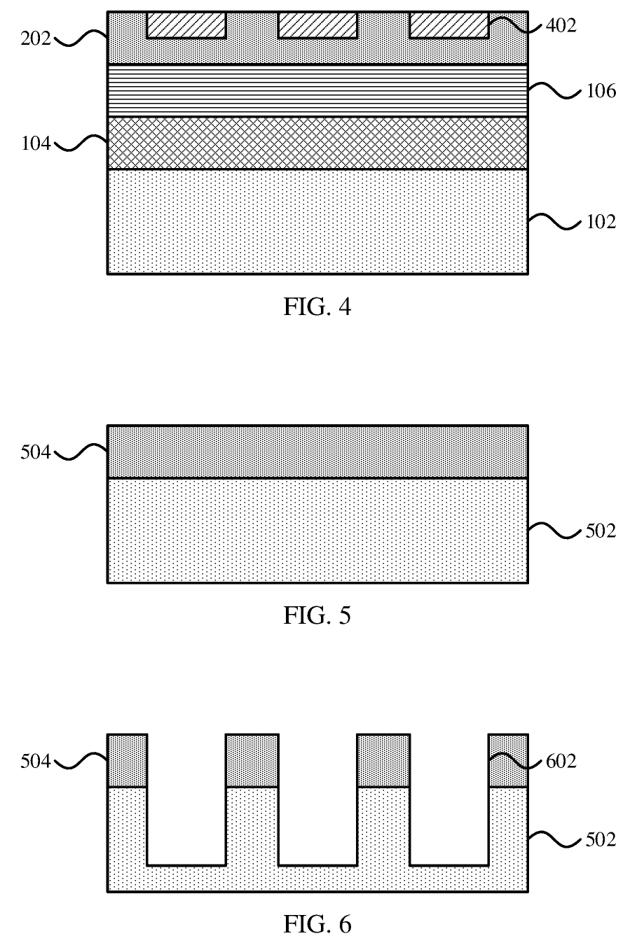

Referring now to FIG. 4, a cross-sectional view of a step in the fabrication of a semiconductor device is shown. Conductive material is formed in the trenches 302, and is polished back to the level of the top surface of the first bonding layer 202 using a CMP process. The CMP slurry may be formulated to be unable to dissolve, for example, the material of the first bonding layer 202, resulting in the CMP process’s inability to proceed any farther than that layer. This leaves first heat-conducting structures 402.

The conductive material that makes up the first heat-conducting structures is selected for its thermal conductivity in particular. In contrast to the thermal conductivity of the surrounding dielectric (e.g., about 1.3W/mK), materials such as copper have a thermal conductivity of about 385W/mK. Other metals, such as gold and silver, may have similar thermal conductivities. Non-metallic materials are also contemplated. For example, diamond may have a thermal conductivity of about 1000 W/mK.

Referring now to FIG. 5, a cross-sectional view of a step in the fabrication of a semiconductor device is shown. A second bonding layer 504 is deposited on a handler wafer 502 by any appropriate deposition process. The handler wafer 502 may be formed from any appropriate material, such as silicon. The second bonding layer 504 may be formed from any appropriate material, such as silicon dioxide. An exposed surface of the second bonding layer 504 is polished smooth using a CMP process. The thermal conductivity of silicon is about 148W/mK. While the thermal conductivity of the handler wafer 502 may therefore be sufficient to dissipate heat that is generated in the device layer 104 and the BEOL layers 106, the thermal conductivity of the first bonding layer 202 and the second bonding layer 504 may be significantly lower.

Referring now to FIG. 6, a cross-sectional view of a step in the fabrication of a semiconductor device is shown. Trenches 602 are formed that penetrate through the second bonding layer 504 and into the bulk of the handler wafer 502. The trenches 602 may be formed by creating a photolithographic mask, as described above, and using one or more anisotropic etches to remove material from the second bonding layer 504 and the handler wafer 502.

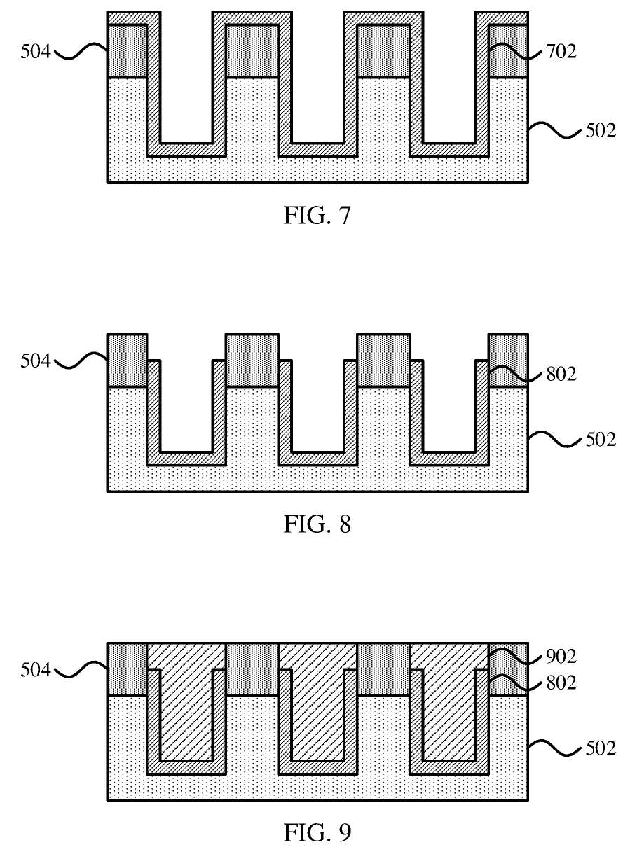

Referring now to FIG. 7, a cross-sectional view of a step in the fabrication of a semiconductor device is shown. A liner 702 is formed within the trenches, for example by conformal deposition of a heat-conducting material such as aluminum nitride or boron nitride with a thin layer of tantalum nitride or tantalum. The liner 702 may be formed by any appropriate conformal deposition process, such as atomic layer deposition (ALD) or (CVD) to an exemplary thickness between about 5nm and about 12nm. Excess heat-conducting material may be removed from the top surface of the second bonding layer 504 by, e.g., a CMP. The liner 702 serves to prevent diffusion between a heat conducting material and the semiconductor of the handler wafer 502. The thin layer of tantalum/tantalum nitride promotes copper adhesion.

Referring now to FIG. 8, a cross-sectional view of a step in the fabrication of a semiconductor device is shown. The liner 702 is chamfered to recess the liner 702 along the sidewalls of the trenches 602, producing chamfered liner 802. Chamfering may be performed by partially filling the trenches 602 with, e.g., an organic planarizing layer that can be deposited using, e.g., a flowable CVD. In some embodiments the partial fill may be accomplished by filling the trenches with a sacrificial material and then partially etching the sacrificial material back using a timed sacrificial etch.

Exposed portions of the deposited liner 702 may be selectively etched away, while portions that are protected by the sacrificial material are preserved. The sacrificial material can then be removed by, e.g., an ashing process that leaves the chamfered liner 802 within the trenches 602.

Referring now to FIG. 9, a cross-sectional view of a step in the fabrication of a semiconductor device is shown. Heat-conducting material, such as copper, is deposited by any appropriate deposition process to fill the trenches 602. Although copper is specifically contemplated for use due to its heat-conducting properties, other heat-conducting materials may be used instead. It is specifically contemplated that the heat-conducting material may be the same as is used for the first heat-conducting structures 402, but it should be understood that the materials may differ.

Excess heat-conducting material may be removed by a CMP process that stops on the second bonding layer 504 to form second heat-conducting structures 902. The chamfered liner 802 prevents diffusion of the heat conducting material into the bulk of the handler wafer 502, and the chamfered portion exposes part of the second bonding layer 504, which promotes bonding between the heat-conducting material and the oxide of the second bonding layer 504 at this interface.

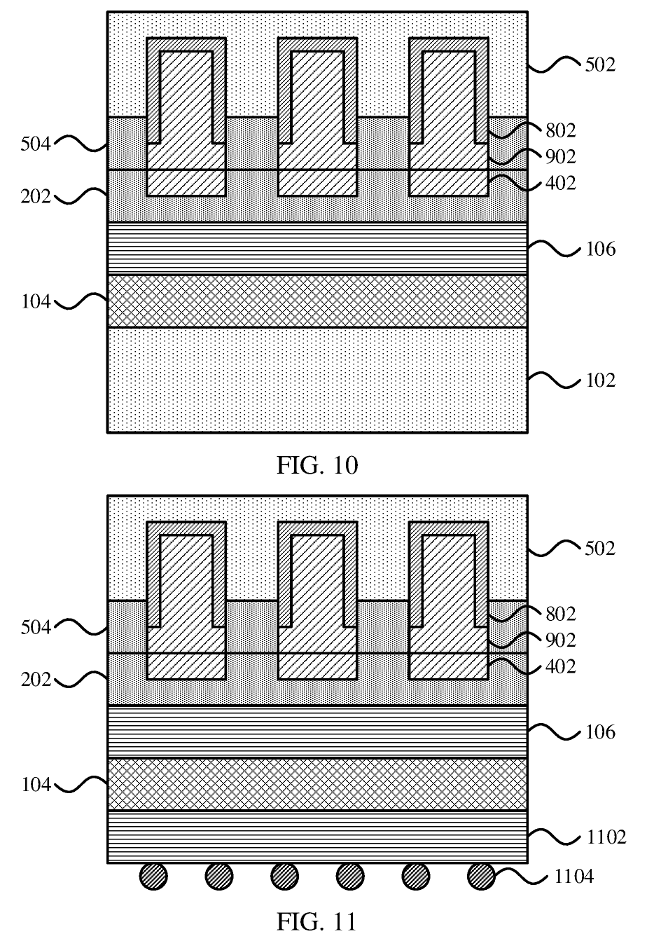

Referring now to FIG. 10, a cross-sectional view of a step in the fabrication of a semiconductor device is shown. The handler wafer 502 is flipped and the second bonding layer 504 is bonded to the first bonding layer 202. This puts the first heat-conducting structures 402 into contract with the second heat-conducting structures 902, creating heat-conducting channels. Hybrid bonding may be used to provide a permanent bond that combines dielectric and embedded metal. Hybrid bonding may be performed face-to-face to vertically connect die-to-wafer or wafer-to-wafer via closely spaced metal pads. The chamfered liner 802 extends part-way through the combined bonding layers.

Because the thermal conductivity of the material(s) of the heat-conducting channels is substantially higher than the thermal conductivity of the surrounding material (e.g., silicon dioxide and silicon), heat may be transmitted through the heat-conducting channels to reach the handler wafer 502 where it can be dissipated, without being trapped in the device layer 104 and the BEOL layers 106 by the bonding oxide that holds the handler wafer 502 to the BEOL layers 106.

Referring now to FIG. 11, a cross-sectional view of a step in the fabrication of a semiconductor device is shown. The semiconductor substrate 102 is removed, for example using a CMP process that stops on the device layer 104. BSPDN layers 1102 are formed on a back side of the device layer 104, opposite to the BEOL layers 106. The BSPDN layers 1102 may include layers of dielectric material with trenches filled with conductive material to form vias and interconnects that provide power to components of the device layer 104.

The semiconductor device may be mounted to another device or wafer using solder bumps 1104. These solder bumps 1104 may include conductive material that is reflowed to create electrical connections between the semiconductor device and the other device or wafer, for example interfacing with vias and interconnects in the BSPDN layers 1102. The handler wafer 502 may thus continue to be used to safely manipulate the semiconductor device until it is installed. During operation of the semiconductor device, heat generated in the device layer 104 may travel through the heat-conducting structures and into the handler wafer 502, where it can be dissipated by any appropriate active or passive means.

Passive heat dissipation may include fins or heat sinks that help to radiate heat into the surrounding environment by convection. Active heat dissipation may include pumping coolant, whether air or liquid, across the handler wafer 502 or a passive heat dissipation structure in thermal contact with the handler wafer 502. Active heat dissipation may also include thermoelectric heat pumps or any other appropriate heat rejection mechanism.

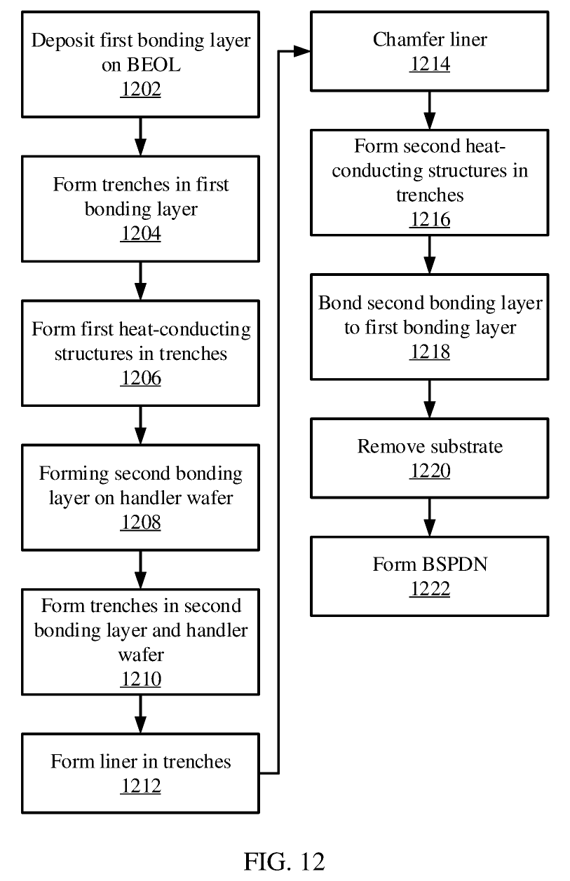

Referring now to FIG. 12, a method for forming a semiconductor device is shown. Given a device layer 104 on a semiconductor substrate 102 and BEOL layers 106, block 1202 deposits the first bonding layer 202 on the BEOL layers 106 using any appropriate deposition process. Block 1204 forms trenches 302 in the first bonding layer 202 and block 1206 forms first heat-conducting structures 402 in the trenches 302.

Block 1208 forms second bonding layer 504 on the handler wafer 502. Block 1210 forms trenches 602 in the second bonding layer 504 and in the handler wafer 502. Block 1212 then forms liner 702 in the trenches 602 and block 1214 chamfers the liner to form chamfered liner 802. Block 1216 forms second heat-conducting structures 902 in the trenches 602.

Block 1218 bonds the second bonding layer 504 to the first bonding layer 202 using hybrid bonding, creating heat-conducting channels by the combination of the first heat-conducting structures 402 and the second heat-conducting structures 902. Block 1220 removes the semiconductor substrate 102 to expose a back side of the device layer 104. Block 1222 then forms BSPDN layers 1102 on the back side of the device layer 104.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of hybrid bonding for thermal dissipation (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device comprising;
a device layer;
a back-end-of-line layer on the device layer;
a combined bonding layer;
a handler wafer; and
a heat-conducting channel that is partially embedded in the combined bonding layer and partially embedded in the handler wafer.

2. The semiconductor device of claim 1, wherein the heat-conducting channel includes a heat-conducting material and a liner between the heat-conducting material and the handler wafer.

3. The semiconductor device of claim 2, wherein the heat-conducting material is in direct contact with the combined bonding layer.

4. The semiconductor device of claim 2, wherein the liner extends part-way through the combined bonding layer.

5. The semiconductor device of claim 2, wherein the heat-conducting material includes a first portion within the handler wafer and part of the combined bonding layer and a second portion within the combined bonding layer, the first portion and the second portion being bonded to one another.

6. The semiconductor device of claim 2, wherein the heat-conducting material is copper, the liner is formed from aluminum nitride, and the handler wafer is formed from silicon.

7. The semiconductor device of claim 1, further comprising a backside power distribution network on a side of the device layer opposite to the back-end-of-line layer.

8. A semiconductor device comprising;
a device layer;
a back-end-of-line layer on the device layer;
a backside power distribution network on a side of the device layer that is opposite to the back-end-of-line layer;
a combined bonding layer;
a handler wafer; and
a plurality of heat-conducting channels that are partially embedded in the combined bonding layer and partially embedded in the handler wafer.

9. The semiconductor device of claim 8, wherein the plurality of heat-conducting channels include a heat-conducting material and a liner between the heat-conducting material and the handler wafer.

10. The semiconductor device of claim 9, wherein the heat-conducting material is in direct contact with the combined bonding layer.

11. The semiconductor device of claim 9, wherein the liner extends part-way through the combined bonding layer.

12. The semiconductor device of claim 9, wherein the heat-conducting material includes a first portion within the handler wafer and part of the combined bonding layer and a second portion within the combined bonding layer, the first portion and the second portion being bonded to one another.

13. The semiconductor device of claim 9, wherein the heat-conducting material is copper, the liner is formed from aluminum nitride, and the handler wafer is formed from silicon.

14. A method of forming a semiconductor device, comprising:
forming first trenches in a first bonding layer that is on a device layer;
forming first heat conducting structures in the first trenches;
forming second trenches in a second bonding layer that is on a handler wafer;
forming a liner in the second trenches;
forming second heat conducting structures in the second trenches; and
bonding the first bonding layer to the second bonding layer, with the first heat conducting structures bonding to the second heat conducting structures.

15. The method of claim 14, further comprising chamfering the liner before forming the second heat conducting structures.

16. The method of claim 15, wherein chamfering includes:
partially filling the second trenches with a sacrificial material;
etching away exposed portions of the liner; and
removing the sacrificial material to exposes a chamfered liner.

17. The method of claim 15, wherein the liner includes aluminum nitride and the first heat conducting structure and second heat conducting structure include copper.

18. The method of claim 14, wherein forming the second trenches includes anisotropically etching through the second bonding layer and partially into the handler wafer.

19. The method of claim 18, wherein forming the first trenches includes anisotropically etching partially into the first bonding layer.

20. The method of claim 14, wherein the bonding includes forming heat conducting channels from the first heat conducting structures and the second heat conducting structures.
